(19) United States
(12) Patent Application Publication
(10) Pub. No.: US 2021/0376174 A1
(43) Pub. Date: Dec. 2, 2021

(54) SOLAR CELL MODULE AND PHOTOVOLTAIC POWER GENERATION SYSTEM

(71) Applicant: Kabushiki Kaisha Toshiba, Tokyo (JP)

(72) Inventors: Soichiro SHIBASAKI, Nerima (JP); Miyuki SHIOKAWA, Kawasaki (JP); Naoyuki NAKAGAWA, Setagaya (JP); Sara YOSHIO, Taito (JP); Mutsuki YAMAZAKI, Yokohama (JP); Hiroki HIRAGA, Saitama (JP); Kazushige YAMAMOTO, Yokohama (JP); Yuya HONISHI, Yokohama (JP); Takeshi NIIMOTO, Kawasaki (JP)

(73) Assignee: Kabushiki Kaisha Toshiba, Tokyo (JP)

(21) Appl. No.: 17/404,409

(22) Filed: Aug. 17, 2021

Related U.S. Application Data
(62) Division of application No. 15/698,392, filed on Sep. 7, 2017.

(30) Foreign Application Priority Data
Sep. 21, 2016 (JP) 2016-184900
Mar. 22, 2017 (JP) 2017-056694
Jun. 27, 2017 (JP) 2017-125122

(51) Int. Cl. H01L 31/05; H01L 31/02; H02S 40/34; H01L 31/043; H02S 40/36; H01L 31/0463; H01L 31/042; H01L 31/0465

(52) U.S. Cl. CPC H01L 31/0504; H01L 31/02021; H02S 40/34; H01L 31/043; F24S 70/30; H01L 31/0463; H01L 31/042; H01L 31/0465; H02S 40/36

(57) ABSTRACT

A solar cell module of an embodiment includes: a first solar panel having a plurality of first sub modules each including a plurality of first solar cells; and a second solar panel layered with the first solar panel, the second solar panel having a plurality of second solar cells. The first solar panel exists on the side where light is incident. The first solar panel and the second solar panel are electrically connected in parallel. The first solar cells included in the first submodules are electrically connected in series. The first submodules are electrically connected in parallel.

### CROSS-REFERENCE TO RELATED APPLICATION

This application is based upon and claims the benefit of priority from Japanese Patent Applications No. 2016-184900, filed on Sept. 21, 2016, No. 2017-056694 filed on Mar. 22, 2017, and No. 2017-125122 filed on Jun. 27, 2017; the entire contents of which are incorporated herein by reference.

### FIELD

Embodiments described herein relate to a solar cell module and a photovoltaic power generation system.

### BACKGROUND

As a high-efficiency solar cell, there is a multi-junction (tandem) solar cell. The multi-junction solar ceil is capable of using an efficient cell for each wavelength range, and therefore is expected to achieve a higher efficiency than a single-junction solar cell. Chalcopyrite solar cells, including CIGS solar cells, are known to be highly efficient, and can be a candidate for a top cell if they have a wide band gap. However, there has not fully been studied a method for connecting solar cells with different band gaps in a module in which the solar cells are joined.

### BRIEF DESCRIPTION OF THE DRAWINGS

FIG. 1 is a perspective schematic diagram of a solar cell module according to an embodiment;

FIG. 2 is a schematic diagram of a second solar panel according to an embodiment;

FIG. 3 is a schematic diagram of a first solar panel according to an embodiment;

FIG. 4 is a schematic diagram of the first solar panel according to an embodiment;

FIG. 5 is a perspective schematic diagram of a solar cell module according to an embodiment;

FIG. 6 is a schematic diagram of a first solar panel according to an embodiment;

FIG. 7A is a cross-sectional schematic diagram of a solar cell module according to an embodiment;

FIG. 7B is a cross-sectional schematic diagram of the solar cell module according to an embodiment;

FIG. 7C is a cross-sectional schematic diagram of the solar cell module according to an embodiment;

FIG. 7D is a cross-sectional schematic diagram of the solar cell module according to an embodiment;

FIG. 7E is a cross-sectional schematic diagram of the solar cell module according to an embodiment;

FIG. 7F is a cross-sectional schematic diagram of the solar cell module according to an embodiment;

FIG. 8 is a perspective schematic diagram of a solar cell module according to an embodiment;

FIG. 9 is a cross-sectional schematic diagram of the solar cell module according to an embodiment;

FIG. 10 is a cross-sectional schematic diagram of the solar panel according to an embodiment;

FIG. 11 is a cross-sectional schematic diagram of the solar panel according to an embodiment;

FIG. 12 is a cross-sectional schematic diagram of the solar panel according to an embodiment;

FIG. 13 is a cross-sectional schematic diagram of the solar panel according to an embodiment; and

FIG. 14 is a schematic configuration diagram of a photovoltaic power generation system according to an embodiment.

### DETAILED DESCRIPTION

A solar cell module of an embodiment includes: a first solar panel having a plurality of first submodules each including a plurality of first solar cells; and a second solar panel layered with the first solar panel, the second solar panel having a plurality of second solar cells. The first solar panel exists on the side where light is incident. The first solar panel and the second solar panel are electrically connected in parallel. The first solar cells included in the first submodules are electrically connected in series. The first submodules are electrically connected in parallel.

Embodiments are described in detail below with reference to drawings. Some of reference numerals of overlapping components in the drawings are omitted.

### First Embodiment

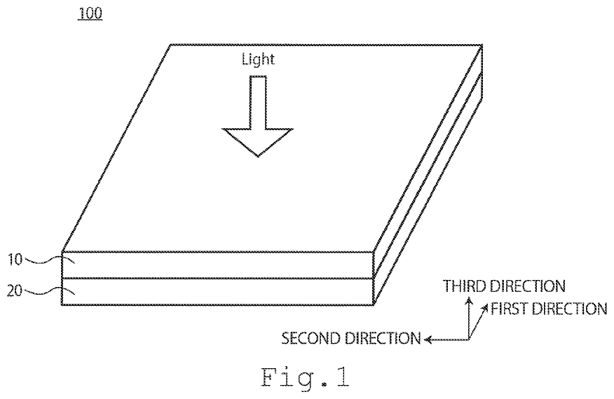

A solar cell module according to a first embodiment has a structure in which two or more solar panels are stacked on top of another. The two or more solar panels are electrically connected in parallel. As shewn in a perspective schematic diagram of FIG. 1, a solar cell module 100 according to the present embodiment includes a first solar panel 10 and a second solar panel 20. The first solar panel 10 and the second solar panel 20 are stacked in a third direction. The first solar panel 10 and the second solar panel 20 are electrically connected in parallel. The depth direction of the solar cell module 100 shall be referred to as a first direction, and the width direction of the solar cell module 100 shall be referred to as a second direction. The first and second directions cross or meet at right angles, and a plane including the first and second directions is parallel to a panel surface of the solar cell module 100. A third direction is perpendicular to the first direction and perpendicular to the second direction. In embodiments, two solar panels are stacked. The embodiments may include a solar cell module having three or more solar panels are stacked.

### First Solar Panel

The first solar panel 10 is a panel existing on the top side of the solar cell module 100, i.e., the side where light is incident. The first solar panel 10 includes a plurality of solar cells with a wide-bandgap light-absorbing layer. The wide-bandgap light-absorbing layer includes, for example, at least one selected from the group consisting of the following: a compound semiconductor, a perovskite-type compound, a transparent oxide semiconductor, and amorphous silicon. The first solar panel 10 according to the first embodiment achieves excellent conversion efficiency by itself. Therefore, it is also preferable that the first solar panel 10 according to the first embodiment is used as stand-alone solar cells without being stacked on top of another solar panel. The first solar panel 10 includes a plurality of first submodules including a plurality of first solar cells.

### Second Solar Panel

The second solar panel 20 is a panel existing on the bottom side of the solar cell module 100, i.e., the side opposite to the light incident side. The second solar panel 20 includes a plurality of solar cells that generate electricity from transmitted light that has passed through the first solar panel 10. The second solar panel 20 includes a plurality of second submodules including a plurality of second solar cells.

Second solar cells of the second solar panel 20 have polycrystalline, monocrystalline Si, or a perovskite compound in their light-absorbing layer. The band gap of the polycrystalline, monocrystalline Si, or a perovskite compound light-absorbing layers is a narrower band gap than that of the light-absorbing layers of first solar cells.

The second solar panel 20 is, for example, a panel using any of the following types of solar cells: PERC (Passivated Emitter and Rear Contact cell) type, PERL (Passivated Emitter and Rear Locally diffusion cell) type and PERT (Passivated Emitter and Rear Totally diffusion cell) type, back contact type (Interdigitated Back Contact cell), and heterojunction (HIT) type.

Electricity generated by the first solar panel 10 and the second solar panel 20 is converted and then is stored, transmitted, or consumed. To store, transmit, or consume electricity, both electricity generated by the first solar panel 10 and electricity generated by the second solar panel 20 need to be converted by power conversion equipment (a converter). If separate converters are used to convert electricity in the first solar panel 10 and the second solar panel 20, two converters are required. An increase in the number of converters increases the power generation cost. Therefore, even though the number of stacked panels is two or more, the solar cell module 100 has a power output terminal (plus/minus)for only a single system because the panels are electrically connected in parallel. Even when the conversion efficiency is improved by using multi-junction solar cells, if the power generation cost increases, which is not preferable in terms of investment capital recovery despite the improvement in the conversion efficiency.

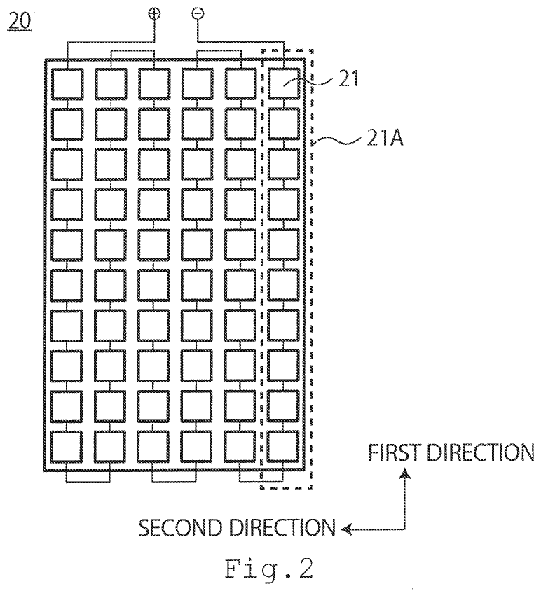

As shown in a schematic diagram of FIG. 2, the second solar panel 20 includes a plurality of second submodules 21A, and each of the second submodules 21A includes a plurality of second solar cells 21. The second solar cells 21 included in the second submodule 21A is electrically connected in series. The plurality of the second submodules 21A is arranged in linear arrays in the second direction. The plurality of the second submodules 21A is electrically connected in series. One of the second submodules 21A is surrounded by broken line. The second solar panel 20 generally has a configuration in which a plurality of the second submodules 21 of polygonal-shaped (e.g., square-shaped) second solar cells 21 electrically connected in series in the first direction are arranged in linear arrays in the second direction, and all the second solar cells 21 are electrically connected in series. Incidentally, the shape of the second solar cells 21 can be a curved polygon of which the linear portions and vertices are curved. Thin lines coupling the second solar cells 21 are electrical wiring that connects the second solar cells 21 in series. The first solar panel 10 is stacked on top of this second solar panel 20, and these solar panels need to have a structure to match respective output voltages of the first solar panel 10 and the second solar panel 20 and also increase the total amount of electricity generated by the first solar 10 and the second solar panel 20. When a plurality of solar panels are electrically connected in parallel, the output voltage obtained through the parallel connection becomes the lowest voltage. Accordingly, the difference in output voltage among the solar panels electrically connected in parallel is preferably as small as possible.

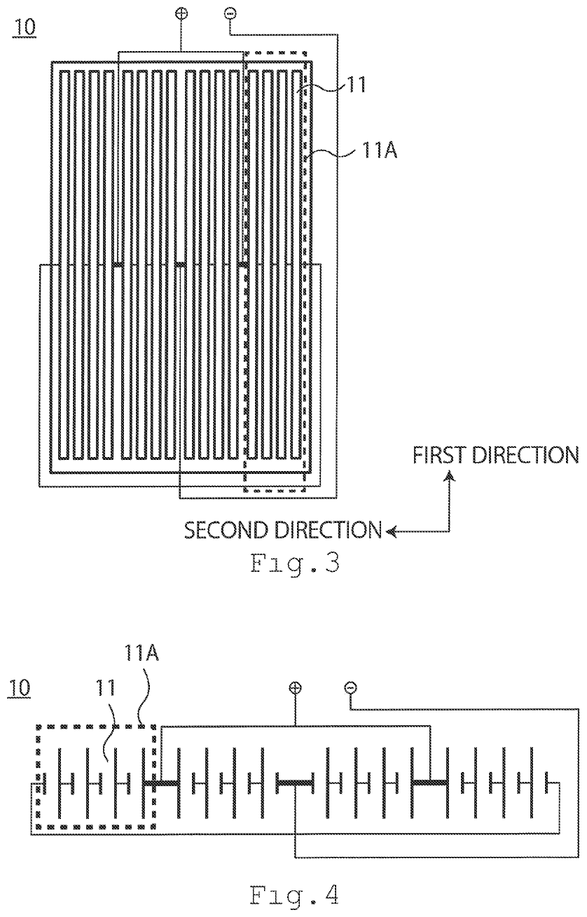

FIG. 3 shows a schematic diagram of the first solar panel 10. The first solar panel 10 includes a plurality of first submodules 11A, and each of the first submodules 11A includes a plurality of first solar cells 11. FIG. 4 shows a schematic circuit diagram. of the first solar panel 10 shown in FIG. 3. A plurality of first solar cells 11 of the first solar panel 10 are configured that the first direction is a longitudinal direction of the first solar cells 11, unlike the second solar cells 21 of the second solar panel 20. In the schematic diagrams of FIGS. 3 and 4, thin lines coupling the first solar cells 11 are electrical wiring that connects the first solar cells 11 in series. Furthermore, in the schematic diagrams of FIGS. 3 and 4, thick lines coupling the first solar cells 11 are electrical wiring that connects the first solar cells 11 in parallel. FIGS. 3 and 4 show a configuration in which four series connection groups of four first solar cells 11 connected in series are connected in parallel. In the schematic diagrams of FIGS. 3 and 4, the first solar cells 11 are arranged so that respective polarities of the first submodules 11A alternate positive and negative; alternatively, the first solar cells 11 can be arranged so that the first submodules 11A have the same electrical polarity, and wiring for parallel connection can be further installed.

The upper and lower electrodes of each first solar cell 11 of the first solar panel 10 need to be transparent electrodes. Transparent electrodes have a higher resistance than metal electrodes. If all the first solar cells 11 are connected in series in the second direction, the area of one cell increases, and the increase in resistance of the transparent electrodes decreases the conversion efficiency of the first solar panel 10. If the width of the first solar cells 11 in the second direction is adjusted in consideration of the resistance of the transparent electrodes, and all the first solar cells 11 are connected in series, the output voltage of the first solar panel 10 does riot match that of the second solar panel 20. Furthermore, for example, if the first solar panel 10 includes one solar cell, the difference in output voltage between the first solar panel 10 and the second solar panel 20 becomes larger.

Accordingly, preferably, the first solar panel 10 includes a plurality of first submodules 11A of the first solar cells 11 electrically connected in series in the second direction, and the plurality of first submodules 11A are electrically connected in parallel in the second direction. By adopting this configuration, the first solar panel 10 can match the output voltage with that of the second solar panel 20, while having a connection configuration of the first solar cells 11 having the high conversion efficiency. The difference in output voltage between the first solar panel 10 and the second solar panel 20 is preferably 2.0 V or less. Preferably, the smaller the difference in output voltage, the smaller the loss caused by the difference in output voltage. Therefore, the difference in output voltage between the first solar panel 10 and the second solar panel 20 is more preferably 1.5 V or less or 1.0 V or less, still more preferably 0.5 V or less. The number of the plurality of first submodules 11A in the first solar panel 10 is preferably two or more but not exceeding ten. If a parallel number is small, the transparent electrode area per first solar cell 11 is large, and the increase in resistance due to the transparent electrodes decreases the power generation efficiency. Furthermore, if a parallel number is too large, the number of the first solar cells 11 in the first solar panel 10 is large, and a non-power-generation region, such as a ring region, increases, and the power generation efficiency decreases.

Here, there is described an example of the solar cell module 100 in which the first solar panel 10 using CGSS (Cu_{0.95}GaSe_{1.95}S_{0.05}) with an open circuit voltage Voc of 0.95 V in its light-absorbing layer and the second solar panel 20 using polycrystalline Si with Voc of 0.66 V in its light-absorbing layer are stacked.

The second solar panel 20 includes six arrays of second submodules 21A that are electrically connected in series; each of the second submodules 21A includes ten second solar cells 21 using Si in their light-absorbing layer that are electrically connected in series. The open circuit voltage Voc of these second solar cells 21 is 0.66 V. As 60 cells with Voc of 0.66 V are connected in series, the open circuit voltage Voc of the second solar panel 20 is 39.6 V (a stand-alone value, which decreases to 37.8 V after the top panel is put thereon). On the other hand, the open circuit voltage Voc of the first solar cells 11 using CGSS in their light-absorbing layer is 0.95 V. To match Voc of the first solar panel 10 with that of the second solar panel 20, i.e., Voc of 39.6 V, 41 arrays of first solar cells 11 are preferably connected in series. If 41 arrays of first solar cells 11 with Voc of 0.95 V are connected in series, Voc of the first solar cells 11 is 39.9 V. Such a panel is about 1 m long in both the first and second directions; for example, when the panel is divided into 41 parts in the second direction, the area of the first solar cells 11 is substantially large. Therefore, 41 arrays of first solar cells 11 connected in series are arranged in parallel. A parallel number is two or more but riot exceeding ten. In general, in view of Voc, FF, etc. of the bottom panel with the top panel put thereon, it should be set so that the difference in Voc at the maximal output is small.

### Second Embodiment

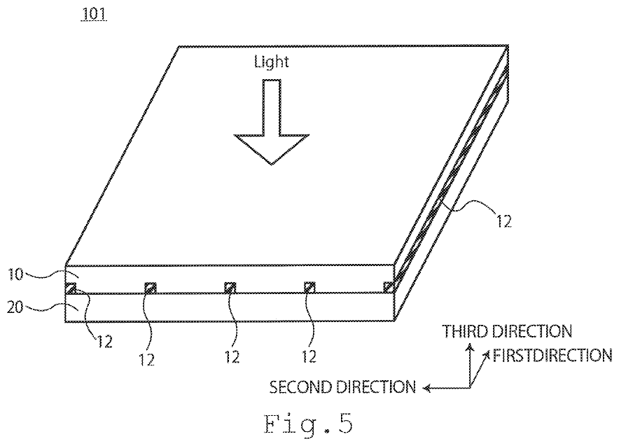

A solar cell module according to a second embodiment has a structure in which two or more solar panels are stacked on top of another. The two or more solar panels are electrically connected in parallel. As shown in a perspective schematic diagram of FIG. 5, a solar cell module 101 according to the present embodiment includes a first solar panel 10 and a second solar panel 20. The first solar panel 10 and the second solar panel 20 are stacked in the third direction. The first solar panel 10 and the second solar panel 20 are electrically connected in parallel. The first solar panel 10 includes busbars 12 that connect first solar cells in the first solar panel 10 in parallel. Except for the busbars 12, the solar cell module 101 according to the second embodiment is similar to the solar cell module 100 according to the first embodiment. Description of the same parts as in the first embodiment is omitted.

### Busbar

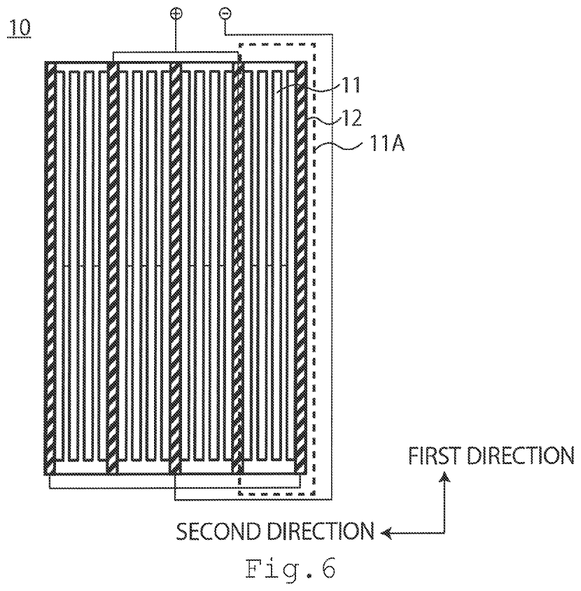

The busbars 12 are metallic plates that connect a plurality of first submodules 11A in the second direction. FIG. 6 shows a schematic diagram of the first solar panel 10 according to the second embodiment. The busbars 12 are metal wiring extending in the first direction. The busbars 12 are arranged in arrays in the second direction of the first solar panel 10. The busbars 12 are arranged at both ends of the first solar panel 10 and in between the plurality of first submodules 11A. Metal used in the busbars 12 is not particularly limited. For example, the busbars 12 are preferably wiring containing at least one selected from the group consisting of Al, Cu, Au, Ag, Mo, and W. The width of the busbars 12 is preferably 1 mm or more but not exceeding 6 mm. If the busbars 12 are too thin, the resistance becomes high, and it is difficult to collect current properly, which is not preferable. Furthermore, portions where the busbars 12 are installed are non-power-generation regions. Therefore, if the busbars 12 are too thick, the amount of generated electricity decreases, which is not preferable. Moreover, the height of the busbars 12 is not particularly limited; however, if the busbars 12 are too high, it is difficult to wire; therefore, the height of the busbars 12 is preferably 2 mm or less or 1 mm or less. The analysis of the solar cell module, such as the height of the busbars 12, can be performed through upper surface observation and cross-sectional observation. Elemental analysis is performed as necessary.

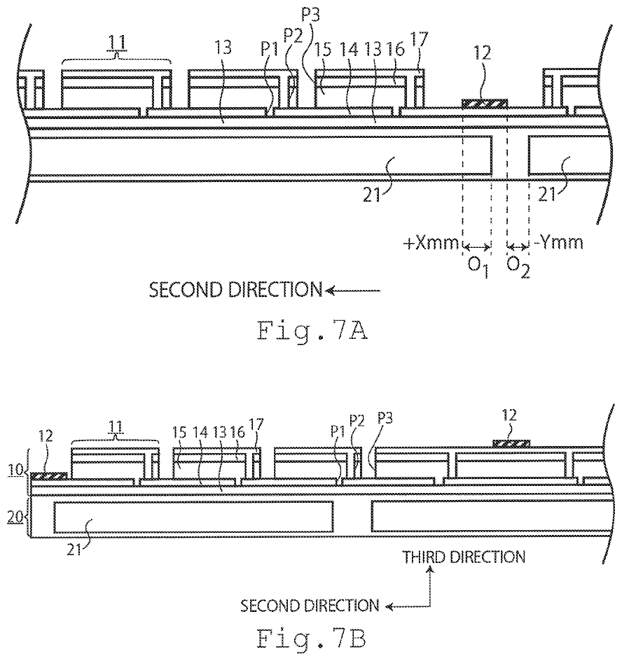

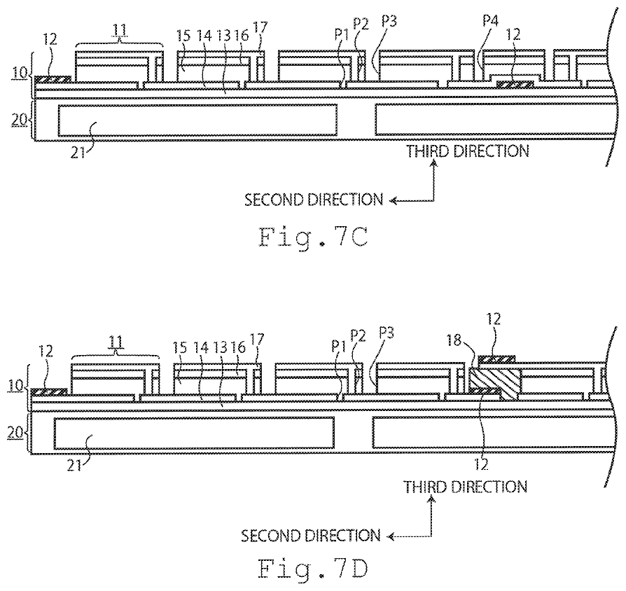

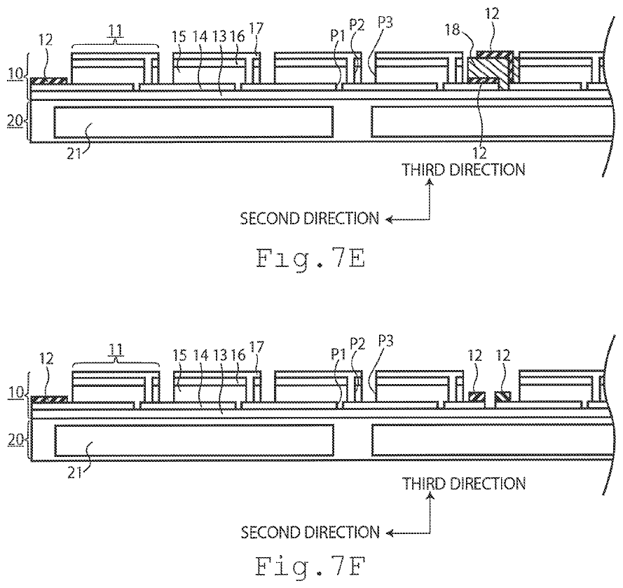

FIG. 7 shows a cross-sectional schematic diagram of the solar cell module 100. In the schematic diagram of FIG. 7, there are the first solar panel 10 having first solar cells 11 and the second solar panel 20 having second solar cells 21. The first solar panel 10 shown in the schematic diagram of FIG. 7 includes the busbars 12 and the plurality of first solar cells 11 that each include a substrate 13, a first electrode 14, a light-absorbing layer 15, a buffer layer 16, and a second electrode 17. In FIG. 7, the busbars 12 are configured to be in direct contact with the first electrodes 14; alternatively, the busbars 12 can be configured to be in contact with the second electrodes 17. P1, P2, and P3 represent sections in patterns 1, 2, and 3, respectively. FIG. 7 shows an example of a substrate-type substrate configuration; however, the first solar panel 10 can adopt a superstrate-type substrate configuration. If the superstrate-type substrate configuration is adopted, the substrate 13 can bear tempered glass on the side of a light receiving surface, which makes the first solar panel 10 lighter. In the case of the substrate-type substrate configuration, after being manufactured, the first solar panel 10 can be coated with resin, and turned over and stacked on top of the second solar panel 20.

FIGS. 7A, 7E, 7C, 7D, 7E, and 7F represent a total of six patterns of schematic diagrams. In FIG. 7A, the busbar 12 is installed on the first electrode 14, and the first electrode 14 exists between the busbar 12 and the substrate 13.

In FIG. 7B, the busbar 12 is installed on the second electrode 17, and the second electrode 17 exists between the busbar 12 and the light-absorbing layer 15.

In FIG. 7C, the busbar 12 is installed on the substrate 13, and the busbar 12 exists between the substrate 13 and the first electrodes 14. Sections P4 exist at both ends of the busbar 12 in the schematic diagram of FIG. 7C. if the busbar 12 and the second electrode 17 can be wired in parallel, the sections P4 do not have to be formed. Also in the configurations shown in the schematic diagrams of FIGS. 7A, 7E, and 7C, the first solar cells 11 are arranged to be symmetric about the busbar 12 so that respective polarities of the first submodules 11A alternate positive and negative.

In FIG. 7D, the busbars 12 are installed on the first electrode 14 of the first submodule 11A on the left side of the figure and the second electrode 17 on the right side of the figure, respectively. The two busbars 12 are at least partially overlapped in the third direction. The electric polarity of the busbar 12 on the first electrode 14 is different from the electric polarity of the busbar 12 on the second electrode 17. An insulating film 18 is resin, SiO₂, or the like, and insulates the two busbars 12.

In FIG. 7E, the busbars 12 are installed on the first electrode 14 on the left side of the figure and an insulating film 18, respectively. The busbar 12 on the insulating film 18 is connected to the first electrode 14 on the right side of the figure. The two busbars 12 are at least partially overlapped in the third direction. The polarity of the busbar 12 on the first electrode 14 is different from the polarity of the busbar 12 on the insulating film 18.

In FIG. 7F, the busbars 12 are installed on the first electrode 14 on the left side of the figure and the first electrode 14 of a right side of the figure, respectively. The two busbars 12 are arranged in arrays in the second direction. The polarity of the busbar 12 on the first electrode 14 on the left side of the figure is different from the polarity of the busbar 12 on the first electrode 14 of the right side of the figure. In the configurations shown in the schematic diagrams of FIGS. 7D, 7E, and 7F, the first solar cells 11 are arranged so as to have the same direction of electrical polarity so that respective polarities of the first submodules have the same polarity. Furthermore, in FIG. 7, the first solar cells 11 are exposed; however, it is preferable that The first solar cells 11 are coated with, for example, resin.

### Substrate

As the substrate 13 in the second embodiment, it is preferable to use soda lime glass, or glass in general, such as quartz, super white glass, and chemically strengthened glass, and resin, such as polyimide and acrylic, can also be used.

### First Electrode

The first electrode 14 in the second embodiment is an electrode of the first solar panel 10. The first electrode 14 is, for example, a transparent electrode containing a semiconductor film formed on the substrate 13. The first electrode 14 exists between the substrate 13 and the light-absorbing layer 15. The first electrode 14 can contain a thin film. As the first electrode 14, a semiconductor film containing at least ITO (Indium-Tin Oxide) can be used. On ITO on the side of the light-absorbing layer 15, a carrier-doped layer containing oxide, such as SnO₂, TiO₂, ZnO:Ga or ZnO:Al, can be lamdnated. ITO and SnO₂ can be laminated from the side of the substrate 13 toward the side of the light-absorbing layer 15, or ITO, SnO₂, and TiO₂ can be laminated from the side of the substrate 13 toward the side of the light-absorbing layer 15. The layer in contact with a light-absorbing layer of the first electrode 14 is preferably any one of the following oxide layers: ITO, SnO₂, and TiO₂. Furthermore, a layer containing oxide, such as SiO₂, can be further installed between the substrate 13 and ITO. The film of first electrode 14 can be formed on the substrate 13 by sputtering or the like. The film thickness of the first electrode 14 is, for example, 100 nm or more but not exceeding 1000 nm. In the case where the solar cells in the second embodiment are used in a multi-junction solar cell, it is preferable that the solar cells in the second embodiment exist the top cell side or the middle cell side, and the first electrodes 14 are transparent semiconductor films.

### Light-Absorbing Layer

The light-absorbing layer 15 in the second embodiment is at least one type layer of a compound semiconductor, a perovskite-type compound, a transparent oxide semiconductor, and amorphous silicon. The light-absorbing layer 15 is a layer forming a p-n junction with the buffer layer 16. If the light-absorbing layer 15 is p-type, the buffer layer 16 is n-type; if the light-absorbing layer 15 is n-type, the buffer layer 16 is p-type. The light-absorbing layer 15 exists between the first electrodes 14 and the buffer layer 16. If the light-absorbing layer 15 is homojunction type, the buffer layer 16 can be omitted.

The light-absorbing layer 15 can use, as a light-absorbing layer, a compound semiconductor layer having a chalcopyrite structure, such as Cu(In,Ga)Se₂, CuInTe₂, CuGaSe₂, Cu(In,Al)Se₂,Cu(Al,Ga) (S,Se)₂, or CuGa(S,Se)₂,Ag (In,Ga)Se₂, Cu(In,Ga) (S,Se)₂, or a compound semiconductor layer, such as CdTe, (Cd,Zn,Mg) (Te,Se,S), or (In,Ga)₂(S,Se,Te)₃. Furthermore, the light-absorbing layer 15 can also use a compound semiconductor layer having a kesterite structure or stannite structure represented by CZTS (Cu₂ZnSnS₄) or a CdTe layer. The film thickness of the light-absorbing layer 15 is, for example, 800 nm or more but not exceeding 3000 nm.

A transparent oxide semiconductor, such as Cu₂O can be used as the light-absorbing layer 15.

A combination of elements helps to adjust the band gap to an intended value. The intended value of the band gap is, for example, 1.0 eV or more but not exceeding 2.7 eV.

The light absorbing layer 15 provided on the side of a top cell and having a large band gap is preferable because power generation in the second solar cell at the bottom side increases due to have wider band gap in the light absorbing layer 15 provided on the side of a top cell. The light absorbing layer 15 having more wider band gap, such as Cu2_{O}, (Cd, Zn, Mg) (Te, Se, S) or (In, Ga)₂ (S, Se, Te)₃ can be preferably used.

Besides the above, the light-absorbing layer 15 can use a Perovskite type compound or amorphous silicon layer represented by CH₃NH₃PbX₃ (X is at least one or more types of halogen).

### Buffer Layer

The buffer layer 16 in the second embodiment is an n-type or p-type semiconductor layer. The buffer layer 16 exists between the light-absorbing layer 15 and the second electrode 17. The buffer layer 16 is a layer in direct contact with the surface of the light-absorbing layer 15 on the opposite side of the surface facing toward the first electrode 14. Then, the buffer layer 16 is a layer forming a heterojunction with light-absorbing layer 15. The buffer layer 16 is preferably an n-type or p-type semiconductor of which the Fermi level is controlled so as to obtain a solar cell with a high open circuit voltage.

In the case where the light-absorbing layer 15 is a chalcopyrite-type compound, a kesterite-type compound, or a stannite-type compound, the buffer layer 16 can use, for example, Zn_{1-y}M_{y}O₁₋ₓSₓ, Zn_{1-y-z}Mg_{z}M_{y}O, ZnO₁₋ₓSₓ, Zn_{1-z}mg_{z}O (M is at least one element selected from a group of B, Al, In, and Ga) CdS, etc. The thickness of the buffer layer 16 is preferably 2 nm or more but not exceeding 800 nm. The film of buffer layer 16 is formed, for example, by sputtering or chemical bath deposition (CBD). When the film of buffer layer 16 is formed by CBD, the buffer layer 16 can be formed on the light-absorbing layer 15, for example, by a chemical reaction of metal salt (for example, CdSO₄) and sulfide (thiourea) with complexing agent (ammonia) in aqueous solution. In the case where a chalcopyrite-type compound not containing In in IIIb group elements, such as a CuGaSe₂ layer, a AgGaSe₂ layer, a CuGaAlSe₂ layer, and a CuGa (Se, S)₂ layer is used in the light-absorbing layer 15, CdS is preferable as the buffer layer 16.

In the case where the light-absorbing layer 15 is CdTe, n-type CdS is preferable as the buffer layer 16.

In the case where the light-absorbing layer 15 is a perovskite-type compound, the buffer layer 16 is a so-called n-type compact layer. As the compact layer, one or more layers of oxides selected from the group consisting of titanium oxide, zinc oxide, allium oxide, and the like are preferable.

In the case where the light-absorbing layer 15 is amorphous silicon, the buffer layer 16 is preferably a-SiC:H because it has a wide band gap and is easy-to-form in a process.

### Oxide Layer

The oxide layer in the second embodiment is a thin film that is preferably installed between the buffer layer 16 and the second electrode 17. The oxide layer is a thin film containing any of the following compounds: Zn₁₋ₓMgₓO, ZnO_{1-y}S_{y}, and Zn₁₋ₓmgₓO_{1-y}S_{y} (0≤x, y<1). The oxide layer can be configured not to cover the whole surface the buffer layer 16 facing toward the second electrode 17. For example, the oxide layer only has to cover 50% of the surface of the buffer layer 16 on the side of the second electrode 17. Other candidates include AlO_{z}, SiO_{z}, SiN_{z}, and wurtzite-type such as AlN, GaN, and BeO. If the volume resistivity of the oxide layer is 1 Ωcm or more, there is an advantage that it is possible to suppress leakage current deriving from a low-resistance component that is likely to exist in the light-absorbing layer 15. Incidentally, in the second embodiment, the oxide layer can be omitted. The oxide layer is an oxide particle layer, and preferably has many voids therein. The intermediate layer is not limited to the above-mentioned compounds and physical property, and only has to be a layer contributing to the improvement in the conversion efficiency of the solar cell. The intermediate layer can be multiple layers with different physical properties.

### Second Electrode

The second electrode 17 second embodiment is an electrode film that transmits light such as sunlight therethrough and has conductivity. The second electrode 17 is in direct contact with the surface of an intermediate layer or the buffer layer 16 on the opposite side of the surface facing toward the light-absorbing layer 15. The joined light-absorbing layer 15 and buffer layer 16 exist between the second electrode 17 and the first electrode 14. The film of second electrode 17 is formed, for example, by sputtering in the Ar atmosphere. The film of second electrode 17 can use, for example, ZnO:Al using a ZnO target containing 2 wt % alumina (Al₂O₃) ZnO:B with B dopant from diborane triethylboron.

### Third Electrode

A third electrode in the second embodiment is an electrode of the first solar cell 11, and is a metal film formed on the second electrode 17 on the opposite side of the side of the light-absorbing layer 15. As the third electrode, a conductive metal film, such as Ni and Al, can be used. The film thickness of the third electrode is, for example, 200 nm or more but not exceeding 2000 nm. Furthermore, in the case where the resistance value of the second electrode 17 is low, and a series resistance component is negligible, the third electrode can be omitted.

### Antireflection Coating

Antireflection coating in the second embodiment is a film for making it easy to introduce light into the light-absorbing layer 15, and is formed on the second electrode 17 or on the third electrode on the opposite side of the side of the light-absorbing layer 15. As the antireflection coating, for example, it is preferable to use MgF₁ or SiO₂. Incidentally, in the second embodiment, the antireflection coating can be omitted. The film thickness of each layer needs to be adjusted according to its refractive index; however, it is preferable to evaporate the film to be 70 to 130 nm (more preferably, 80 to 120 nm) thick.

A method for manufacturing the first solar cells 11 and the sections P1, P2, and P3 in patterns 1, 2, and 3 are briefly described. The first electrode 14 is formed on the substrate 13, and is subjected to scribing, and the section P1 is formed. Then, films of the light-absorbing layer 15 and the buffer layer 16 are formed. The light-absorbing layer 15 is formed on the section P1 as well. The light-absorbing layer 15 and the buffer layer 16 are subjected to scribing, and the section P2 is formed. Then, the second electrode 17 is formed on the buffer layer 16. The second electrode 17 is formed on the section P2 as well. Then, the light-absorbing layer 15, the buffer layer 16, and the second electrode 17 are subjected to scribing, and the section P3 is formed. Then, series-connected first solar cells 11 are obtained. The busbars 12 can be formed on the substrate before the film of first electrode 14 is formed, or can be formed after the scribing process for the formation of the section P3.

The first electrode 14 and the second electrode 17 are both a transparent electrode that transmits light therethrough, so tend to have a higher resistance than a metal electrode. Therefore, if the areas of the first electrode 14 and the second electrode 17 are large, the effect of the high resistance of the electrodes becomes prominent. The size of even a small solar panel is about 1200 mm×600 mm, and the size of a large solar panel is about 16000 mm×1000 mm. The area of the solar panel 10 is large, so that just connecting the first solar cells 11 in series results in the large areas of the first electrode 14 and the second electrode 17 per first solar cell 11 as well. In the second embodiment, the first submodules 11A are electrically connected in parallel; therefore, the area of a transparent electrode per cell or the width of one cell (the width of a transparent electrode) can be reduced. The area of a transparent electrode is reduced to be small, which increases the number of parallel connections, and increases a non-power-generation region. Therefore, reducing the area of a transparent electrode to be too small is not preferable. Furthermore, electricity generated by the cells flows in the width direction (short direction) that is the second direction. Therefore, by lessening the distance between transparent electrodes in the width direction, the effect of the resistance of the transparent electrodes can be softened. From these facts, the width of the first electrode 14, the width of the second. electrode 17, or the widths of the first electrode 14 and the second electrode 17 are preferably 3 mm or more hut not exceeding 15 mm, more preferably 3.3 mm or more but not exceeding 8 mm, still more preferably 3.5 mm or more but not exceeding 8 mm. Incidentally, the width of the first electrode 14 is the second-direction length of the first electrode 14 facing the substrate 13. Likewise, the width of the second electrode 17 is the second-direction length of the second electrode 17 facing the substrate 13.

### Third Embodiment

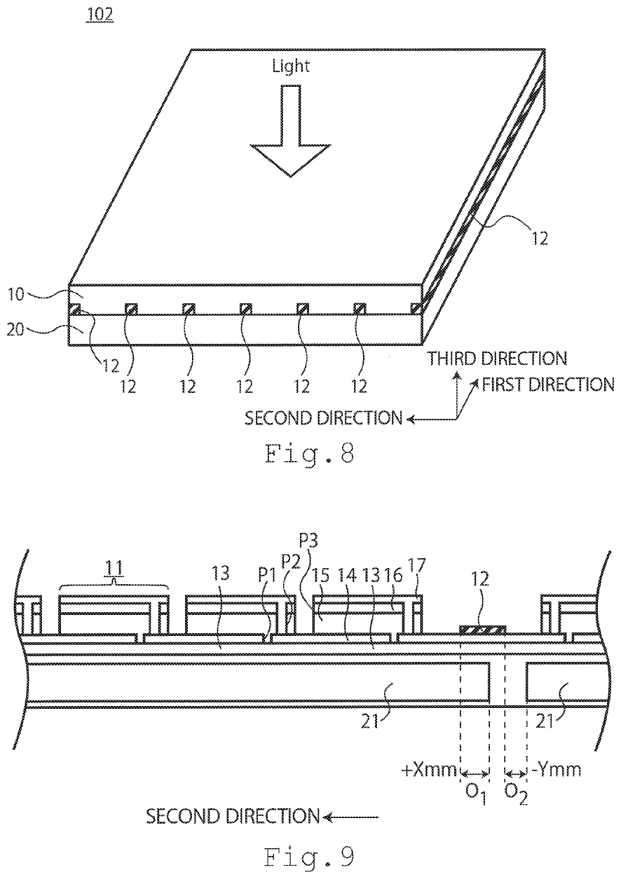

A solar cell module according to a third embodiment has a structure in which two or more solar panels are stacked on top of another. The two or more solar panels are electrically connected in parallel. As shown in a perspective schematic diagram of FIG. 8, a solar cell module 102 according to the present embodiment includes a first solar panel 10 and a second solar panel 20. The first solar panel 10 and the second solar panel 20 are stacked in a third direction. The first solar panel 10 and the second solar panel 20 are electrically connected in parallel. The first solar panel 10 includes busbars 12 that connect first solar cells in the first solar panel 10 in parallel. Except for the number and positions of the busbars 12, the solar cell module 102 according to the third embodiment is similar to the solar cell module 101 according to the second embodiment. Description of the same parts as in the first embodiment is omitted.

If the busbar 12 of the first solar panel 10 overlaps with the second solar cell 21, the amount of light, that, the second solar cell 21 receives is reduced. If the busbar 12 between first submodules 11A exists on a non-power-generation region that is a region between a plurality of second submodules 21A of the second solar cells 21, the effect on the light receiving amount of the second solar cells 21 is less, which is preferable. The second solar cells 21 are all electrically connected in series. Therefore, when the light receiving amount of one cell is reduced due to a busbar 12, the overall output voltage decreases, which is not preferable.

When respective polarities of the first submodules 11A of the first solar panel 10 alternate positive and negative, it is preferable that the number of busbars 12 is (n/m)+1, where n denotes the number of arrays of the plurality of second submodules 21A of the second solar cells 21 and m denotes a divisor of n, and the busbars 12 are arranged at equally spaced intervals. Of the busbars 12, two exist at both ends of the first solar panel 10 in the second direction. It is preferable that, as shown in a cross-sectional schematic diagram of the solar cell module in FIG. 9, the remaining (n/m)−1 busbars exist on a non-power-generation region of the second solar panel 20 that is a region between the plurality of second submodules 21A of the second solar cells 21. It is preferable that the busbars 12 located at both ends of the first solar panel 10 also exist on the non-power-generation region of the second solar panel 20 where no second solar cells 21 exist. Incidentally, the required number of the busbars 12 varies according to a parallel number of the first submodules 11A of the first solar panel 10. Furthermore, when the first solar cells 11 are arranged so that all the first submodules 11A of the first solar panel 10 have the same polarity, it is preferable that the number of busbars 12 is 2(n/m), where n denotes the number of arrays of the plurality of second submodules 21A of the second solar cells 21 and m denotes a divisor of n, and the busbars 12 are arranged at equally spaced intervals. Of the busbars 12, two exist at both ends of the first solar panel 10 in the second direction. It is preferable that the remaining 2(n/m)−2 busbars exist on the non-power-generation region of the second solar panel 20 that is a region between the plurality of second submodules 21A of the second solar cells 21. Incidentally, when the first solar cells 11 are arranged so that some of the first submodules 11A of the first solar panel 10 have the same polarity and the polarities of the other first submodules 11A alternate positive and negative, the number of the busbars 12 is larger than (n/m)+1 and smaller than 2(n/m). It is preferable that the busbars 12 located at both ends of the first solar panel 10 also exist on the non-power-generation region of the second solar panel 20 where no second solar cells 21 exist. If these conditions are met, the busbars 12 are all installed on the non-power-generation region of the second solar cells 21, which is preferable in terms of high-efficiency generation of electricity. The busbars 12 existing on the non-power-generation region of the second solar panel 20 means a state in which, when the busbars 12 are projected onto the side of the second solar panel 20 in the third direction, the projected busbars 12 overlap with a region where no second solar cells 21 exist.

When a busbar 12 exists on the non-power-generation region of the second solar panel 20, it is preferable that the overlapping distance between the busbar 12 on the non-power-generation region of the second solar panel 20 when projected onto the side of the second solar panel 20 in the third direction and the second solar cells 21 is small. An overlapping distance O₁ between the busbar 12 and the second solar cell 21 is +X mm in. FIG. 9. −Y mm is an overlapping distance O₂ between the busbar 12 and the second solar cell 21 when the busbar 12 does not overlap with the second solar cell 21. The overlapping distance between the busbar 12 and the second solar cell 21 is preferably 0 mm or more but not exceeding 2 mm. Assuming that normal light is incident on the second solar panel 20, the power generation loss is about 1% when the overlapping distance is 1 mm, which is more preferable than that when the overlapping distance is 0 mm.

### Fourth Embodiment

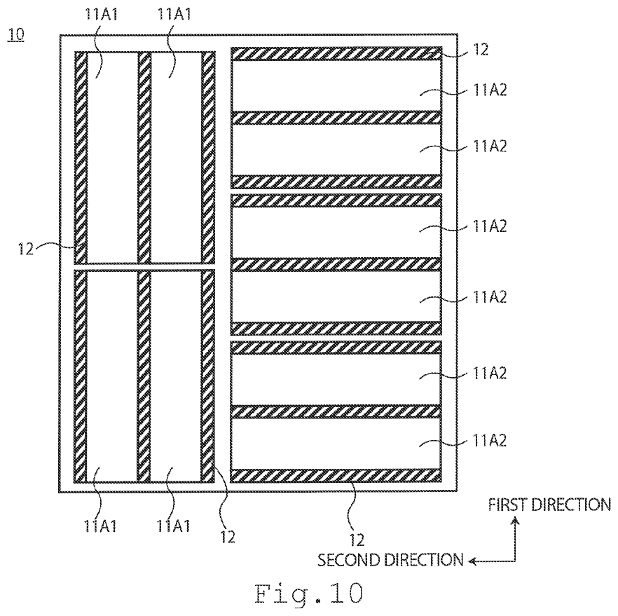

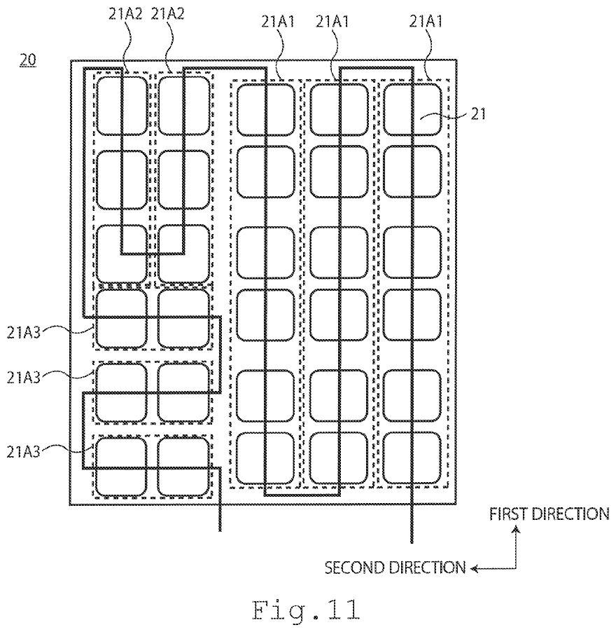

A solar cell module according to a fourth embodiment includes a first solar panel and a second solar panel stacked together with the first solar panel; the first solar panel includes a plurality of first submodules that are electrically connected by busbars and each include a plurality of first solar cells. It is preferable that the two solar panels are electrically connected in parallel. FIG. 10 shows a schematic diagram of a first solar panel 10 according to the fourth embodiment, and FIG. 11 shows a schematic diagram of a second solar panel 20 according to the fourth embodiment. The panels shown in FIGS. 10 and 11 have the same size and rectangular shape. A longitudinal direction of a first submodule 11A is the same as a longitudinal direction of first solar cells included in the first submodule 11A.

In the first solar panel 10 shown in FIG. 10, first submodules 11A1 of which the longitudinal direction is the first direction and first submodules 11A2 of which the longitudinal direction is the second direction are arranged. Busbars 12 are connected to first submodules 11A between and at both ends of the first submodules 11A, and electricity generated by the first submodules 11A is configured to be collected by the busbars 12. Incidentally, in the schematic diagram of FIG. 10, a plurality of pairs of two first submodules 11A electrically connected in parallel by a busbar 12 are depicted. The pairs of two first submodules 11A connected to busbars 12 are configured to be electrically connected in parallel. The electrical connection between the busbars 12 is not shown in the schematic diagram of FIG. 10; however, the busbars 12 are connected to one another as with the cases of the first solar panels 10 according to the second and third embodiments. The direction, the number, etc. of the first submodules 11A can be appropriately selected according to the size and shape of the panel.

In the second solar panel 20 shown in FIG. 11, second submodules 21A1 and 21A2 of which the longitudinal direction is the first direction and second submodules 21A3 of which the longitudinal direction is the second direction are arranged. Second solar cells 21 of the second submodules are electrically connected in series in the longitudinal direction of each second submodule (indicated by a solid line). The second submodules 21A are configured to be all electrically connected in series. The direction, the number, etc. of the second submodules 21A can be appropriately selected according to the size and shape of the panel.

The busbars 12 of the first solar panel 10 exist on a non-power-generation region of the second solar panel 20 where no second solar cells 21 are installed. Even if the submodules are not uniform in size and direction and the busbars 12 are not uniform in direction, the busbars 12 are less likely to be shielded by the second solar cells 21. The first solar panel 10 can be configured so as to increase the amount of light reaching a power-generation region of the second solar panel 20. Also in this configuration, the power generation voltage of the first solar panel 10 can be matched with that of the second solar panel 20, and the first solar panel 10 and the second solar panel 20 can be connected in parallel so as to keep loss low.

### Fifth Embodiment

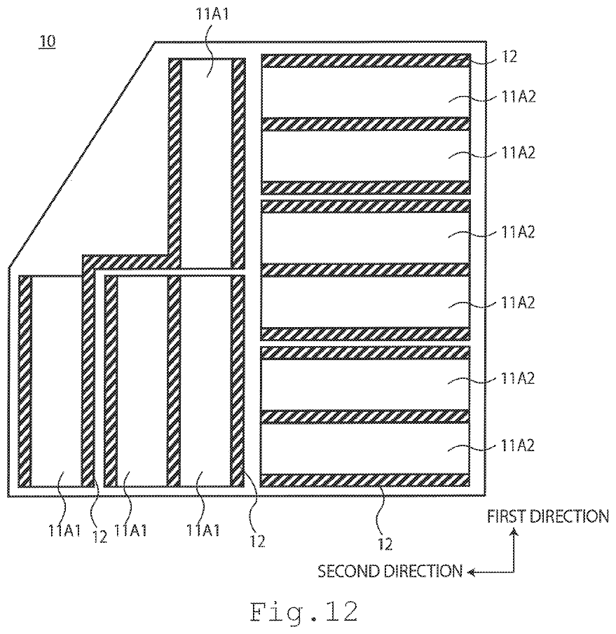

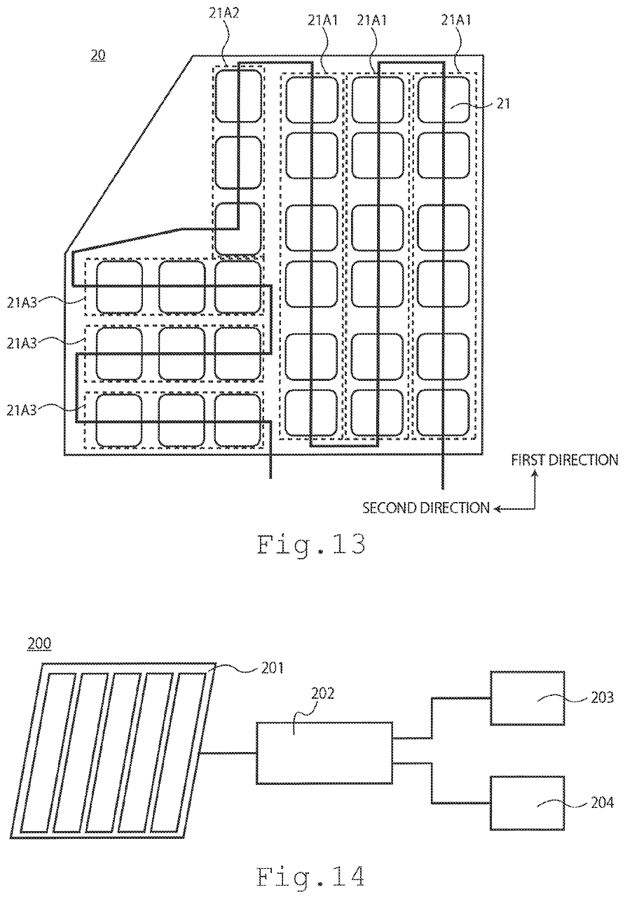

A solar cell module according to a fifth embodiment includes a first solar panel and a second solar panel stacked together with the first solar panel; the first solar panel includes a plurality of first submodules that are electrically connected by busbars and each include a plurality of first solar cells. The solar cell module according to the fifth embodiment is a variation of the solar cell module according to the fourth embodiment. It is preferable that the two solar panels are electrically connected in parallel. FIG. 12 shows a schematic diagram of a first solar panel 10 according to the fifth embodiment, and FIG. 13 shows a schematic diagram of a second solar panel 20 according to the fifth embodiment. The panels shown in FIGS. 12 and 13 have the same size and polygonal shape. When a solar cell module is installed on the roof or the like, if the area the solar cell module is installed is not rectangular, the installation area of the solar cell module can be efficiently extended by using the module according to the present embodiment.

The solar cell module according to the fifth embodiment is the same as the solar cell module according to the fourth embodiment, except that they differ in the shape of the panels and the arrangement or configuration of the submodules.

In the case where the panel shape is polygonal, if the submodules are arranged in the same manner as the fourth embodiment, some of the submodules protrude from the panels, so the arrangement and configuration of the submodules are altered as shown in the schematic diagrams of FIGS. 12 and 13.

In the first solar panel 10 shown in the schematic diagram of FIG. 12, the arrangement of the submodules shown in FIG. 10 is adjusted to the polygonal shape of the panel by moving the left upper first submodule 11A1 next to the lower first submodules 11A1. The separate first submodules 11A1 as shown in FIG. 12 can also be electrically connected by a busbar 12.

In the second solar panel 70 shown in the schematic diagram of FIG. 13, the configuration of the submodules shown in FIG. 11 is reconstructed in such a manner that the left upper second submodule 21A2 composed of three solar cells 21 is removed, and the three lower second submodules 21A3 are each added with. one solar cell 21.

When the solar panels shown in FIGS. 12 and 13 are stacked together, as with the fourth embodiment, the busbars 12 of the first solar panel 10 exist on a non-power-generation region of the second solar panel 20 where no second solar cells 21 are installed. Even if the submodules are not uniform, in size and direction and the busbars 12 are not uniform in direction, the busbars 12 are less likely to be shielded by the second solar cells 21. The first solar panel 10 can be configured so as to increase the amount of light reaching a power-generation region of the second solar panel 20. Also in this configuration, the power generation voltage of the first solar panel 10 can be matched with that of the second solar panel 20, and the first solar panel 10 and the second solar panel 20 can be connected in parallel so as to keep loss low.

### Sixth Embodiment

The solar cell modules 100, 101, and 102 according to the first to third embodiments and the solar cell modules according to the fourth and fifth embodiments can be used as a power generator that generates electricity in a photovoltaic power generation system according to a sixth embodiment. The photovoltaic power generation system according to the present embodiment is for generating electricity by using a solar cell module, and, specifically, includes a solar cell module configured to generate electricity, a unit configured to convert generated electricity, and an electricity storage unit configured to store the generated electricity or a load configured to consume the generated electricity. FIG. 14 shows a schematic configuration diagram of a photovoltaic power generation system 200 according to the fourth embodiment. The photovoltaic power generation system 200 in FIG. 14 includes a solar cell module 201 (100, 101, 102), a converter 202, a storage battery 203, and a load 204. Either the storage battery 203 or the load 204 can be omitted. The load 204 can be configured to be able to use electric energy stored in the storage battery 203 as well. The converter 202 is a circuit or device including an element, such as a DC-DC converter, a DC-AC converter, or an AC-AC converter, configured to perform voltage transformation and power conversion, such as DC-AC conversion. As the configuration of the converter 202, a suitable configuration can be adopted according to the output voltage and the configurations of the storage battery 203 and the load 204.

Solar cells included in the solar cell module 201 having received light generate electricity, and its electric energy is converted by the converter 202 and then is stored in the storage battery 203 or consumed by the load 204. Preferably, the solar cell module 201 is installed with a solar-light tracking/drive device configured to constantly turn the solar cell module 201 to face to the sun, or is provided with a light collector configured to collect solar light, or added with a device or the like for improving the power generation efficiency.

Preferably, the photovoltaic power generation system 200 is used in immovables, such as houses, commercial facilities, and factories, or is used in movables, such as vehicles, aircrafts, and electronic devices. By using a photoelectric converter with excellent conversion efficiency in the solar cell module 201 in the present embodiment, the amount of generated electricity is expected to increase.

The present embodiments are specifically explained below on the basis of examples; however, the present embodiments are not limited to the following examples.

### EXAMPLE 1

In Example 1, Cu_{0.95}GaSe_{1.95}S_{0.05} is used in light-absorbing layers of first solar cells of a first solar panel, and polycrystalline Si is used in light-absorbing layers of second solar cells of a second solar panel. The first solar panel and the second solar panel have the same size of 1650 mm in the first direction × 991 mm in the second direction. The first solar cells all have the same width of 3.94 mm (the width of second electrodes of the cells is also the same), and are arranged in 246 arrays in the second direction. The 41 cells are electrically connected in series, and six first submodules 11A are formed. A total of seven 3-mm busbars are installed at both ends and in between the six first submodules 11A, and are electrically connected in parallel. The busbars are arranged at the positions not overlapping with the second solar cells. Six arrays of second submodules 21A of ten second solar cells, which are arranged in the first direction in each array and are connected in series, are arranged in the second direction. The six series second submodules 21A are also connected in series, and the 60 second solar cells are connected in series.

First, with respect to each of the first solar panel and the second solar panel, Jsc, Voc, and the conversion efficiency are found; then, the conversion efficiency of a solar cell module in which the first solar panel and the second solar panel are stacked on top of another and electrically connected in parallel is found. Table 1 shows the results together with results of other examples and comparative examples.

### EXAMPLE 2

Example 2 is The same as Example 1, except that the busbars of the first solar panel and the first solar cells are arranged so that all the busbars overlap by 1 mm with the second solar cells.

### EXAMPLE 3

Example 3 is the same as Example 1, except that the busbars 2.0 of the first solar panel and the first solar cells are arranged so that all the busbars overlap by 2 mm with the second solar cells.

### EXAMPLE 4

The first solar cells all had the same width of 4.74 mm (the width of the second electrodes of the cells is also the same), and are arranged in 205 arrays in the second direction. The 41 cells are electrically connected in series, and five first submodules 11A are formed. A total of six 3-mm busbars are installed at both ends and in between the five first submodules 11A. Then, Example 4 is the same as Example 1, except that the busbars of the first solar panel and the first solar cells are arranged so that the busbars overlap by 2 mm or less with the second solar cells.

### EXAMPLE 5

The first solar cells all had the same width of 7.95 mm (the width of the second electrodes of the cells is also the same), and are arranged in 123 arrays in the second direction. The 41 cells are electrically connected in series, and three first submodules 11A are formed. Example 5 is the same as Example 1, except that a total of four busbars are installed at both ends and in between the three first submodules 11A, and the busbars of the first solar panel and the first solar cells are arranged.

### EXAMPLE 6

The first solar cells all have the same width of 11.96 mm (the width of the second electrodes of the cells is also the same), and are arranged in 82 arrays in the second direction. The 41 cells are electrically connected in series, and two first submodules 11A are formed. Example 6 is the same as Example 1, except that a total of three busbars are installed at both ends and in between the two first submodules 11A, and the busbars of the first solar panel and the first solar cells are arranged.

### EXAMPLE 7

The first solar cells all have the same width of 3.73 mm (the width of the second electrodes of the cells is also the same), and are arranged in 240 arrays in the second direction. The 40 cells are electrically connected in series, and six first submodules 11A are formed. Example 7 is the same as Example 1, except that a total of five busbars are installed at both ends and in between the six first submodules 11A, and the busbars of the first solar panel and the first solar cells are arranged.

### Comparative Example 1

The first solar cells are one array of stand-alone cells with a width of 985 mm (the width of the second electrodes of the cells is also the same). Compare Example 1 is the same as Example 1, except that a total of two busbars are installed at both ends of the first solar panel, and the busbars of the first solar panel and the first solar cells are arranged.

### Comparative Example 2

The first solar cells all have the same width of 24 mm (the width of the second electrodes of the cells is also the same), and are arranged in 41 arrays in the second direction. The 41 cells are electrically connected in series, and one first submodules 11A is formed. Comparative Example 2 is the same as Example 1, except that a total of two busbars are installed at both ends of the first solar panel, and the busbars of the first solar panel and the first solar cells are arranged.

### EXAMPLE 8

Cu_{0.93}GaSe₂ is used in the light absorbing layers of the first solar is of the first solar panel. The first solar cells all have the same width of 3.75 mm (the width of the second electrodes of the cells is also the same), and are arranged in 258 arrays in the second direction. The 43 cells are electrically connected in series, and six first submodules 11A are formed. A total of seven 3-mm busbars are installed at both ends and in between the six first submodules 11A, and are electrically connected in parallel. The busbars are arranged at the positions not overlapping with the second solar cells. Except for these, Example 8 is the same as Example 1.

### EXAMPLE 9

A perovskite compound is used in the light-absorbing layers of the first solar cells of the first solar panel. The first solar cells all have the same width of 4.36 mm (the width of the second electrodes of the cells is also the same), and are arranged in 222 arrays in The second direction. The 37 cells are electrically connected in series, and six first submodules 11A are formed. A total of seven 3-mm busbars are installed at both ends and in between the six first submodules 11A, and are electrical y connected in parallel. The busbars are arranged at the positions not overlapping with the second solar cells. Except for these, Example 9 is the same as Example 1.

### Example 10

Amorphous silicon is used in the light-absorbing layers of the first solar cells of the first solar panel. The first solar cells all have the same width of 3.83 mm (the width of The second electrodes of the cells is also the same), and are arranged in 252 arrays in The second direction. The 42 cells are electrically connected in series, and six first submodules 11A are formed. A total of seven 3-mm busbars are installed at both ends and in between the six first submodules 11A, and are electrically connected in parallel. The busbars are arranged at the positions not overlapping with the second solar cells. Except for these, Example 10 is the same as Example 1.

### EXAMPLE 11

A CdTe compound is used in the light-absorbing layers of the first solar cells of the first solar panel. The first solar cells all have the same width of 3.5 mm (the width of the second electrodes of the cells is also the same), and are arranged in 276 arrays in the second direction. The 46 cells are electrically connected in series, and six first submodules 11A are formed. A total of seven 3-mm busbars are installed at both ends and in between the six first submodules 11A, and are electrically connected in parallel. The busbars are arranged at the positions not overlapping with the second solar cells. Except for these, Example 11 is the same as Example 1.

TABLE 1A

| | | | | Second solar panel (with first | | |
|---|---|---|---|---|---|---|
| | First solar panel | | | solar panel on top thereof) | | |
| | Jsc | | Conversion | Jsc | | Conversion |
| | A | Voc V | efficiency % | A | Voc V | efficiency % |
| Second solar | | | | 9.7 | 39.6 | 18.1 |
| panel alone | | | | | | |
| Example 1 | 5.3 | 39.0 | 10.1 | 5.7 | 37.8 | 10.0 |
| Example 2 | 5.3 | 39.0 | 10.1 | 5.7 | 37.8 | 10.0 |
| Example 3 | 5.3 | 39.0 | 10.1 | 5.6 | 37.8 | 9.9 |
| Example 4 | 5.4 | 39.0 | 10.1 | 5.6 | 37.8 | 9.8 |
| Example 5 | 5.4 | 39.0 | 10.2 | 5.7 | 37.8 | 10.0 |
| Example 6 | 5.4 | 39.0 | 10.1 | 5.7 | 37.8 | 10.0 |
| Comparative | 0.1 | 0.9 | 0.005 | 5.7 | 27.8 | 10.0 |
| example 1 | | | | | | |
| Comparative | 5.4 | 35.1 | 9.2 | 5.7 | 37.8 | 10.0 |
| example 2 | | | | | | |
| Comparative | 1.1 | 194.8 | 10.2 | 5.7 | 37.8 | 10.0 |
| example 3 | | | | | | |
| Example 6 | 5.5 | 38.0 | 10.1 | 5.7 | 37.8 | 10.0 |
| Example 7 | 7.0 | 39.1 | 10.8 | 4.6 | 38.1 | 8.5 |
| Example 8 | 10.0 | 37.7 | 16.4 | 2.4 | 37.4 | 4.2 |
| Example 9 | 6.1 | 37.4 | 9.6 | 5.7 | 37.8 | 10.0 |
| Example 10 | 10.4 | 39.6 | 19.4 | 1.9 | 36.8 | 3.2 |

TABLE 1B

| | Solar cell module |
|---|---|
| | Total conversion efficiency % |
| Second solar panel alone | 18.1 |
| Example 1 | 19.5 |
| Example 2 | 19.4 |
| Example 3 | 19.3 |
| Example 4 | 19.1 |
| Example 5 | 19.5 |
| Example 6 | 19.2 |
| Comparative example 1 | 1.3 |
| Comparative example 2 | 16.6 |
| Comparative example 3 | 19.3 |
| Example 6 | 19.7 |
| Example 7 | 18.4 |
| Example 8 | 18.7 |
| Example 9 | 19.3 |
| Example 10 | 21.5 |

From these examples, it turns out that a panel with an efficiency exceeding that of Si alone can be obtained (even at present). The efficiency of the CGSS or CGS cells has room for improvement. If the efficiency is improved, the open circuit voltage is also improved, so that it will require consideration again, including the number of series connections. Furthermore, the efficiency of the bottom Si solar cell also improves day by day; therefore, a high-efficiency module can be obtained by stacking high-efficiency panels on top of another.

A difference between a band gap of the light absorbing layer of the first solar cell and a band gap of the light absorbing layer of the second solar cell can be increased by using Cu₂O, (Cd, Zn, Mg) (Te, Se, S), (In, Ga)₂ (S, Se, Te)₃, having very wider band gap, as a light absorbing layer of the first solar cell. When the difference between the band gap of the light absorbing layer of the first solar cell and a band gap of the light absorbing layer of the second solar cell increases, the power generation increases because light that contributes to the power generation in the light absorbing layer of the second solar cell increases. By applying such multi-junction solar cell having large difference between the band gaps and also applying the connecting mode of the solar cells, the power generation in the second solar panel on the bottom side, increasing the power generation in the multi-junction solar cell is expected.

Here, some elements are expressed only by element symbols thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1-15. (canceled)

16. A solar cell module comprising:
a first solar panel including a plurality of first submodules each including a plurality of first solar cells; and
a second solar panel layered with the first solar panel; the second solar panel including a plurality of second solar cells, wherein
the first solar panel exists on a side where light is incident,
the first solar panel and the second solar panel are electrically connected in parallel;
the first solar cells included in the first submodules are electrically connected in series, and
the first submodules are electrically connected in parallel,
the first solar cells have a structure in which a longitudinal direction of the first solar cells is a first direction,
the first submodules are electrically connected in parallel in a second direction crossing the first direction, and
the first submodules are connected by busbars of which the longitudinal direction is the first direction.

17. The solar cell module according to claim 16, wherein
the second solar panel includes a plurality of second submodules each including the second solar cells,
the second solar cells of the second submodules are electrically connected in series in the first direction,
the second submodules are arranged in a plurality of lines in the second direction, the second submodules are electrically connected in series, and
when respective polarities of the first submodules alternate positive and negative, the number of the busbars is (n/m)+1, wherein n denotes a parallel number of the second submodules, and m denotes a divisor of n.

18. The solar cell module according to claim 16, wherein an overlapping distance between each busbar and a respective of the second solar cells is 0 millimeters or more but not exceeding 2 millimeters.

19. The solar cell module according to claim 16 wherein the busbars exist at both ends of the first solar panel, and
both ends are ends of the first solar panel in the direction in which the busbars extend.

20. The solar cell module according to claim 16, wherein the busbars include a bulbar which is arranged between the plurality of the first submodules.

21. The solar cell module according to claim 16, wherein a width of the busbars is 1 to 5 mm.

22. The solar cell module according to claim 16, wherein each of the first submodules are directly and electrically connected to two of the busbars whose polarity differ from each other.

23. The solar cell module according to claim 16, wherein
the second solar panel includes a plurality of second submodules each including the second solar cells, and
the second solar cells included in the second submodules are electrically connected in series.

24. A solar cell module comprising:
a first solar panel in which a plurality of first submodules each including a plurality of first solar cells are electrically connected by busbars; and
a second solar panel stacked together with the first solar panel.

25. A photovoltaic power generation system using the solar cell module according to claim 16.
